(19) United States
(12) Patent Application Publication
(10) Pub. No.: US 2024/0266640 A1
(43) Pub. Date: Aug. 8, 2024

(54) ELECTROLYTIC DISCHARGE SYSTEM AND METHOD

(71) Applicant: SHAO-TING DAI, TAINAN CITY (TW)

(72) Inventor: SHAO-TING DAI, TAINAN CITY (TW)

(21) Appl. No.: 18/426,682

(22) Filed: Jan. 30, 2024

(30) Foreign Application Priority Data
Feb. 4, 2023 (TW) 112104016

(51) Int. Cl. H01M 14/00

(52) U.S. Cl. CPC H01M 14/00

(57) ABSTRACT

An electrolytic discharge system and method is disclosed. The method includes: forming an electrolytic circuit by connecting a peripheral switch; performing a process for destroying electrical neutrality, wherein a potential difference is formed between a common electrode and a central electrode due to a difference in material energy levels and/or an electrical neutrality of an electrolyte being destroyed, the common electrode and the central electrode form a self-electrolytic discharge circuit. Thereby, the method can produce output performance with a net energy gain.

### FIELD OF THE INVENTION

The present invention relates to an electrolytic discharge system and method, and more particularly to an electrolytic discharge system and method using spiral induction electrodes.

### BACKGROUND OF THE INVENTION

Electrolysis is an important industrial process, commonly used in electroplating and energy storage technologies. These technologies are mainly based on external power supply. The applied current flows through the electrode material for the electrolyte to perform an electrolysis reaction or to store electrical energy.

As disclosed in Chinese Patent Publication No. CN110731027A, titled “molten salt battery with solid metal cathode”, an energy storage device is provided, comprising at least one electrochemical cell which includes a negative current collector, a negative electrode in electrical communication with the negative current collector, an electrolyte in electrical communication with the negative electrode, a positive current collector, and a positive electrode in electrical communication with the positive current collector and the electrolyte. The positive electrode includes a material that is solid at the operating temperature of the energy storage device.

However, the electrolysis efficiency of the aforementioned patent still needs to be improved.

### SUMMARY OF THE INVENTION

According to one aspect of the present invention, an electrolytic discharge method is provided. The electrolytic discharge method comprises: providing at least three electrodes that are all in contact with an electrolyte in an electrolytic tank, wherein the electrodes include at least one common electrode, a central electrode, and at least one peripheral electrode; connecting a central switch between the adjacent common electrode and the central electrode; connecting a peripheral switch and a power supply unit between the adjacent common electrode and the peripheral electrode; by disconnecting the peripheral switch, the adjacent peripheral electrode, the power supply unit, and the common electrode and/or the central electrode forming an electrolytic circuit through the peripheral switch and the electrolyte; performing a process for destroying electrical neutrality, wherein a potential difference is formed between the common electrode and the central electrode due to a difference in material energy levels of the common electrode and the central electrode and/or an electrical neutrality of the electrolyte being destroyed, the adjacent common electrode and the central electrode form a self-electrolytic discharge circuit through the central switch and the electrolyte.

According to one aspect of the present invention, an electrolytic discharge system is provided. The electrolytic discharge system comprises: an electrolytic tank, configured for storing an electrolyte; at least three electrodes, disposed in the electrolytic tank and being in contact with the electrolyte, the electrodes including at least one common electrode, a central electrode, and at least one peripheral electrode; at least one power supply unit, connected between the adjacent common electrode and the peripheral electrode; at least one a central switch, connected between the adjacent common electrode and the central electrode; at least one peripheral switch, connected between the adjacent common electrode and the power supply unit, or, connected between the adjacent common electrode and the peripheral electrode; wherein by disconnecting the peripheral switch, the adjacent peripheral electrode, the power supply unit, and the common electrode and/or the central electrode form an electrolytic circuit through the peripheral switch and the electrolyte; wherein a process for destroying electrical neutrality is performed, a potential difference is formed between the common electrode and the central electrode due to a difference in material energy levels of the common electrode and the central electrode and/or an electrical neutrality of the electrolyte being destroyed, the adjacent common electrode and the central electrode form a self-electrolytic discharge circuit through the central switch and the electrolyte.

Preferably, the common electrode and/or the central electrode is a spiral induction electrode. The spiral induction electrode extends spirally in an axial direction. In the axial direction, the spiral induction electrode has a first end and an opposing second end. An interior of the spiral induction electrode is fully hollow from the first end to the second end. After the self-electrolytic discharge circuit is formed, a magnetic field is formed on the spiral induction electrode through the potential difference. The magnetic field induces ions of the electrolyte to flow and become an ion flow.

Preferably, in a radial direction perpendicular to the axial direction, the spiral induction electrode has at least two different radial widths. When the magnetic field is formed on the spiral induction electrode, the magnetic field induces the ion flow of the electrolyte to accelerate to pass through the spiral induction electrode, and/or the magnetic field induces an electric current on the spiral induction electrode to increase in magnitude.

Preferably, before connecting the peripheral switch, the central switch is first connected, and then the peripheral switch is connected.

Preferably, when the number of the electrodes is three, the process for destroying electrical neutrality is that after the electrolytic circuit is formed and after an ignition time, the central switch is disconnected and then the peripheral switch is disconnected; the peripheral electrode is removed within a specified time, by connecting the central switch, the potential difference is formed between the common electrode and the central electrode due to the difference in the material energy levels of the common electrode and the central electrode and/or the electrical neutrality of the electrolyte being destroyed.

Preferably, when the number of the electrodes is four or more, before connecting the peripheral switch, the central switch is first disconnected, and then the peripheral switch is connected.

Preferably, when the number of the electrodes is four or more, the process for destroying electrical neutrality is that after an ignition time, the peripheral switch is disconnected; the peripheral electrode is removed within a specified time, by connecting the central switch, the common electrode and the central electrode form the self-electrolytic discharge circuit through the central switch and the electrolyte.

Preferably, when the number of the electrodes is an even number of four or more, one of the common electrodes serves as the central electrode, a polarity of the central electrode is opposite to that of the other common electrodes, and a polarity of the common electrode is opposite to that of the adjacent peripheral electrode.

Alternatively, when the number of the electrodes is an odd number of more than four, a polarity of the central electrode is the same as that of the peripheral electrode, and the polarity of the central electrode is opposite to that of the common electrode.

Preferably, the electrolytic tank is made of an insulating material. The electrolyte is a single electrolyte or a composite electrolyte.

Preferably, the spiral induction electrode is formed by one of a tin-plated copper wire, a silver-plated copper wire, a lead-containing solder wire and a lead-free solder wire, or a combination thereof.

According to the above technical features, the present invention achieves the following effects:

1. The spiral induction electrode extending in a spiral shape generates a magnetic field to induce the ions of the electrolyte to flow, thereby improving the efficiency of the electrolysis effect greatly.

2. The spiral induction electrode with varying radial widths allows for axial gradient changes in the density of the magnetic field, which further induces an increase in electric current and acceleration of the ion flow and further enhances the efficiency of the electrolysis effect.

3. The electrolytic discharge system is first energized with a small amount of electric current and then de-energized after the ignition time. Subsequently, without the need for energization, the spiral induction electrode and the electrolyte obtain several times to dozens of times the electric current output, forming a discharge system with a net gain of energy. Besides, the electrolyte is used for self-electrolytic discharge, which can reduce carbon emissions and save energy greatly.

### BRIEF DESCRIPTION OF THE DRAWINGS

FIG. 1 is a first schematic view of a first embodiment of the present invention, illustrating the electrolytic discharge system;

FIG. 2 is a second schematic view of the first embodiment of the present invention, illustrating that the spiral induction electrode is in contact with the electrolyte;

FIG. 3 is a flow block diagram of the first embodiment of the present invention;

FIG. 4 is a third schematic view of the first embodiment of the present invention, illustrating that both the first switch and the second switch are connected;

FIG. 5 is a fourth schematic view of the first embodiment of the present invention, illustrating that after the first switch and the second switch are disconnected, the third electrode is removed;

FIG. 6 is a fifth schematic view of the first embodiment of the present invention, illustrating that the first switch is connected again;

FIG. 7 is a first schematic view of a second embodiment of the present invention, illustrating the electrolytic discharge system;

FIG. 8 is a flow block diagram of the second embodiment of the present invention;

FIG. 9 is a second schematic view of the second embodiment of the present invention, illustrating that the first switch is disconnected, and both the second switch and the third switch are connected;

FIG. 10 is a third schematic view of the second embodiment of the present invention, illustrating that after the first switch is disconnected and both the second switch and the third switch are disconnected after the ignition time, the third electrode and the fourth electrode are removed;

FIG. 11 is a fourth schematic view of the second embodiment of the present invention, illustrating that the first switch is connected again; and

FIG. 12 is a schematic view of a third embodiment of the present invention, illustrating the electrolytic discharge system.

### DETAILED DESCRIPTION OF THE PREFERRED EMBODIMENTS

Embodiments of the present invention will now be described, by way of example only, with reference to the accompanying drawings.

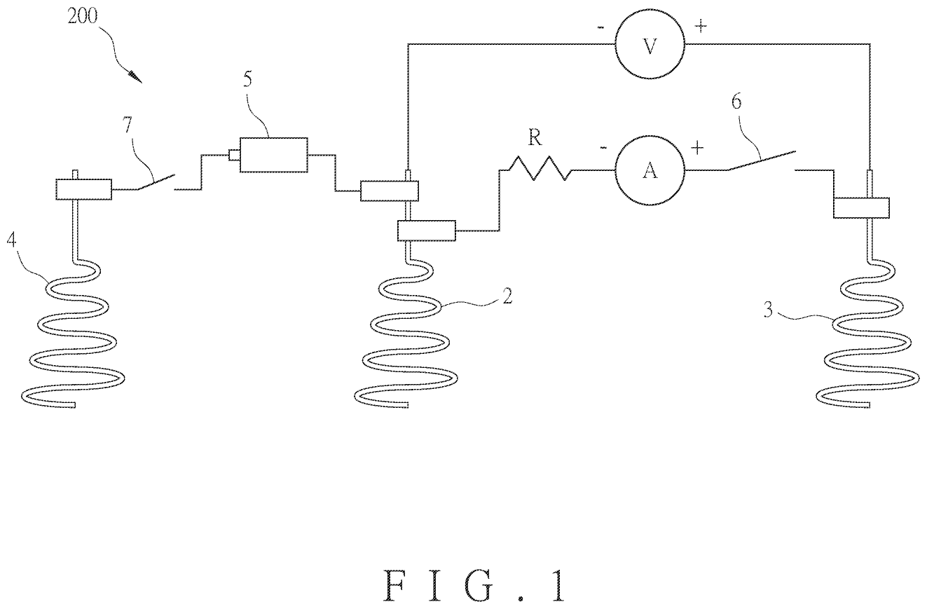

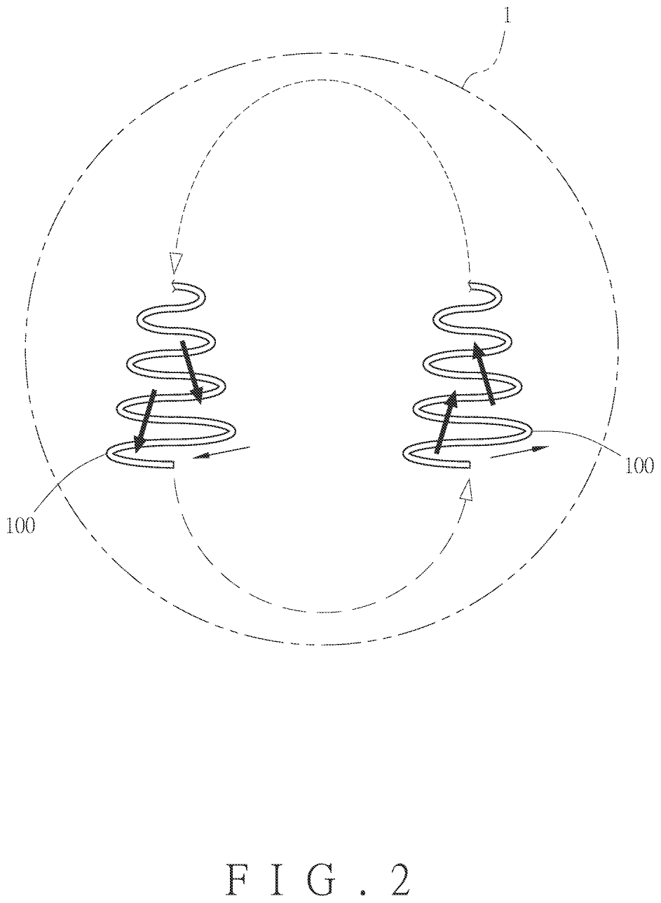

The present invention discloses an electrolytic discharge system and method. FIG. 1 and FIG. 2 illustrate a first embodiment of the electrolytic discharge system 200 of the present invention for performing an electrolytic discharge method of the present invention.

The electrolytic discharge system 200 comprises an electrolytic tank 1, a first electrode 2, a second electrode 3, a third electrode 4, a power supply unit 5, a first switch 6, and a second switch 7.

The electrolytic tank 1 is configured for storing an electrolyte. Preferably, the material of the electrolytic tank 1 is an insulating material. The electrolyte may be a single electrolyte or a composite electrolyte. The complex electrolyte means a mixture of two or more electrolytes, which may be a mixture of acid and salt, salt and salt, or alkali and salt.

The first electrode 2 is disposed in the electrolytic tank 1 and is in contact with the electrolyte.

The second electrode 3 is located close to the first electrode 2. The second electrode 3 is disposed in the electrolytic tank 1 and is in contact with the electrolyte.

The third electrode 4 is located close to the first electrode 2. The third electrode 4 is disposed in the electrolytic tank 1 and is in contact with the electrolyte.

The power supply unit 5 is electrically connected to the first electrode 2 and the third electrode 4.

The first switch 6 connects the first electrode 2 and the second electrode 3.

The second switch 7 connects the first electrode 2 and the power supply unit 5, or connects the third electrode 4 and the power supply unit 5.

When the total number of the electrodes is three, the first electrode 2 serves as a common electrode, the second electrode 3 serves as a central electrode, and the third electrode 4 serves as a peripheral electrode. The first switch 6 serves as a central switch, and the second switch 7 serves as a peripheral switch.

The first electrode 2 or the second electrode 3 is a spiral induction electrode 100. Preferably, both the first electrode 2 and the second electrode 3 are the spiral induction electrodes 100, and even the third electrode 4 and the fourth electrode 5 are also the spiral induction electrodes 100. The material of the spiral induction electrode 100 is one of a tin-plated copper wire, a silver-plated copper wire, a lead-containing solder wire and a lead-free solder wire, or a combination thereof.

The spiral induction electrode 100 extends spirally in an axial direction. In the axial direction, the spiral induction electrode 100 has a first end and an opposing second end. The interior of the spiral induction electrode 100 is fully hollow from the first end to the second end. In a radial direction perpendicular to the axial direction, the spiral induction electrode 100 has at least two different radial widths, so that the spiral induction electrode 100 is gradually enlarged or tapered. In actual implementation, in the radial direction, the spiral induction electrode 100 may have a consistent radial width, instead of being gradually enlarged or tapered.

The first end of the spiral induction electrode 100 is connected to the power supply unit 5. The second end of the spiral induction electrode 100 extends into the electrolyte.

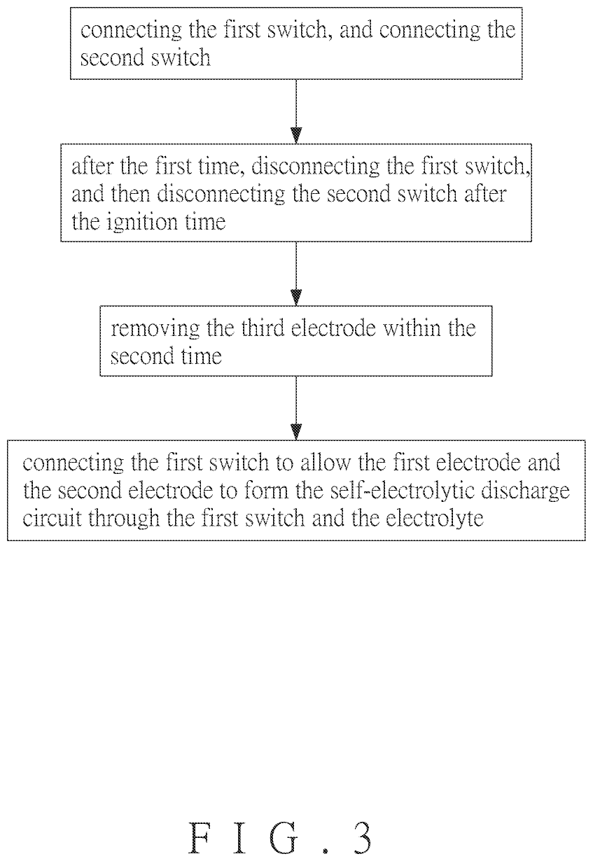

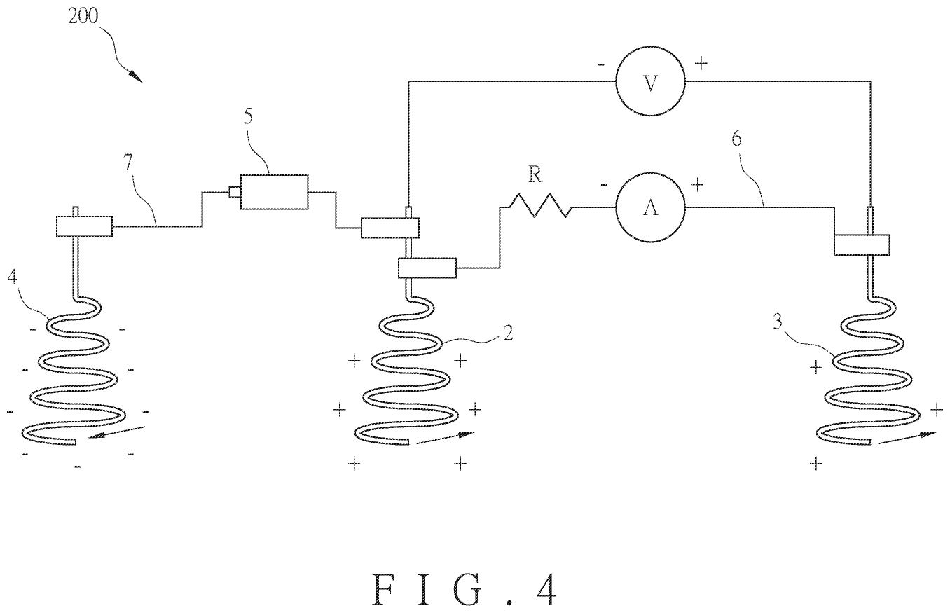

Please refer to FIG. 3 and FIG. 4. For performing the electrolytic discharge method, the first switch 6 is first connected, and then the second switch 7 is connected, so that the first electrode 2, the second electrode 3, the third electrode 4 and the power supply units 5 form an electrolytic circuit through the second switch 7 and the electrolyte.

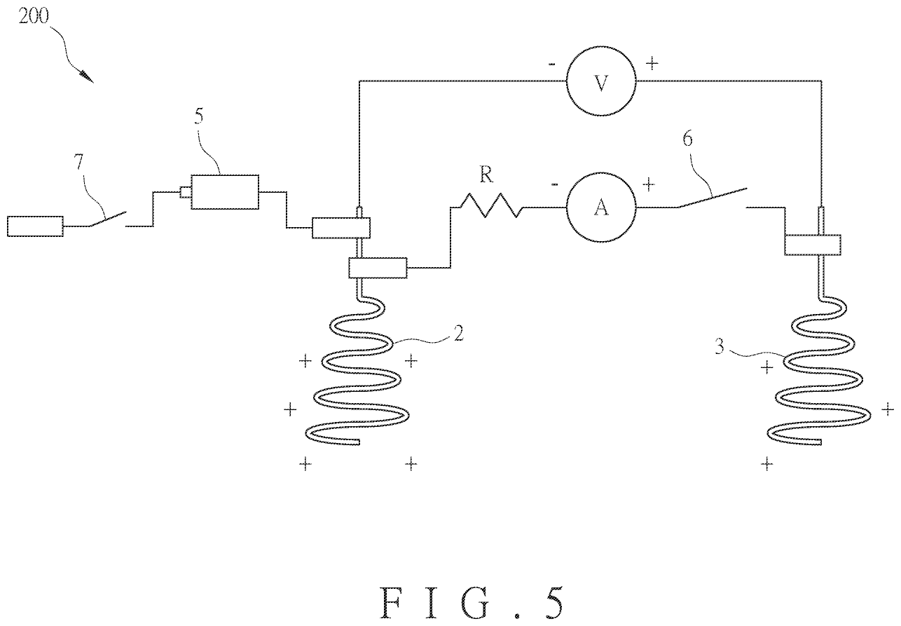

Please refer to FIG. 2, FIG. 3 and FIG. 5. Then, the power supply unit 5 supplies power for a specified time (first time) and then the first switch 6 is disconnected. After an ignition time, for example, 20 seconds to 3600 seconds, the second switch 7 is disconnected. In actual implementation, the ignition time is determined according to the capacity of the electrolytic tank 1. For example, a smaller electrolytic tank 1 may select a shorter ignition time.

The third electrode 4 shown in FIG. 4 is removed within another specified time (second time). For example, the third electrode 4 is quickly removed within 10 seconds to 30 seconds. A potential difference is formed between the first electrode 2 and the second electrode 3 due to the difference in material energy levels of the first electrode 2 and the second electrode 3 and/or the electrical neutrality of the electrolyte being destroyed.

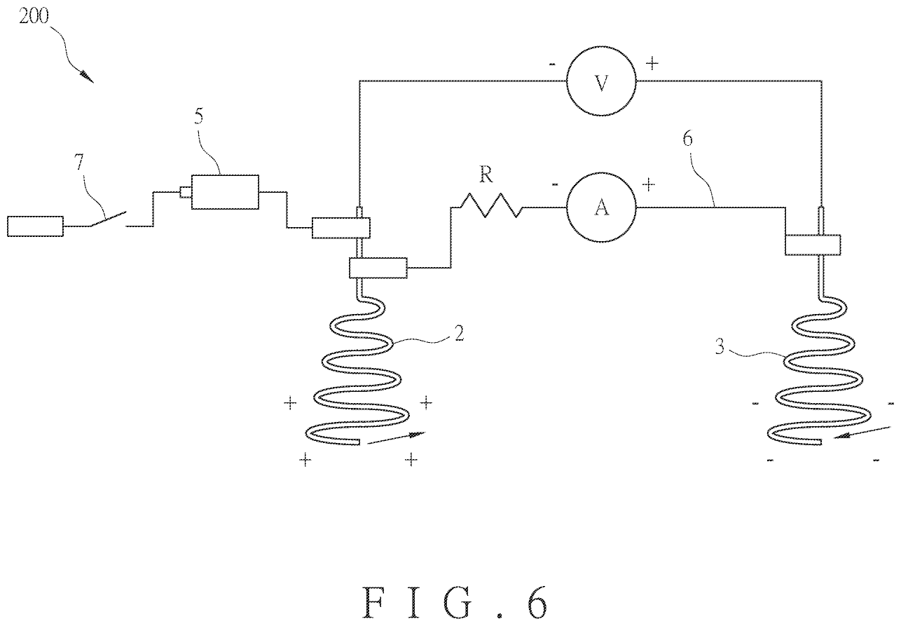

Please refer to FIG. 2, FIG. 3 and FIG. 6. Finally, the first switch 6 is connected, so that the first electrode 2 and the second electrode 3 form a self-electrolytic discharge circuit through the first switch 6 and the electrolyte.

At this time, the potential difference forms an electric current, and the electric current flowing through the spiral induction electrode 100 forms a magnetic field on the spiral induction electrode 100. Due to the shape of the spiral induction electrode 100, the density of the magnetic field changes as the spiral induction electrode 100 is gradually enlarged/tapered, thereby inducing various ions of the electrolyte 2021 to flow and become an ion flow, even inducing the ion flow to accelerate to pass through the spiral induction electrode 100 or inducing the electric current to increase in magnitude, such that the efficiency of the electrolysis effect is improved greatly.

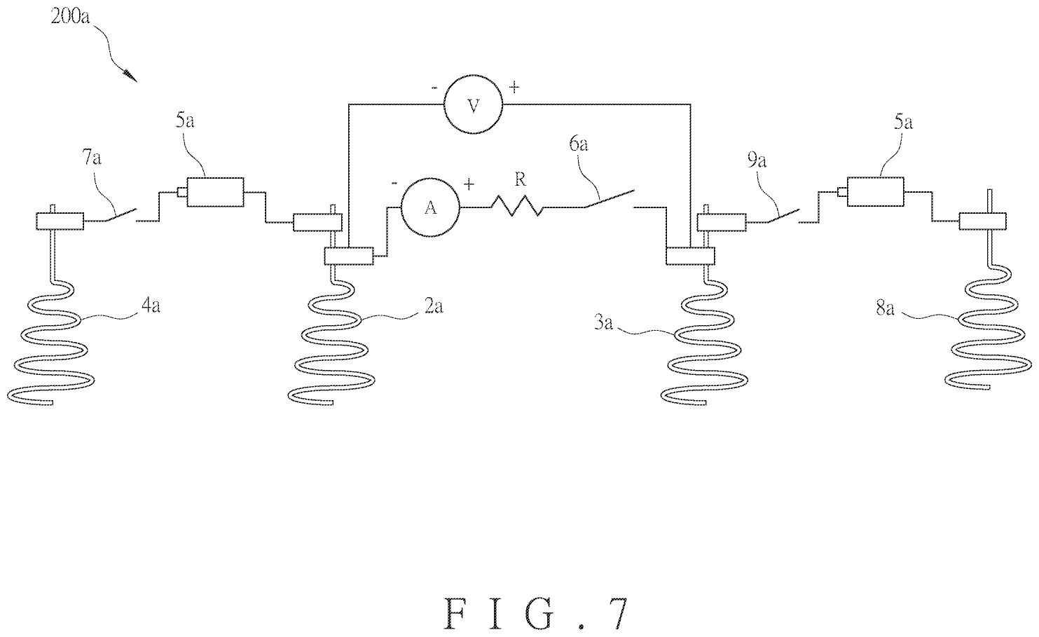

FIG. 7 illustrates a second embodiment of the electrolytic discharge system 200a of the present invention. The second embodiment is substantially similar to the first embodiment with the exceptions described below. The second embodiment further comprises a fourth electrode 8a, a third switch 9a, and another power supply unit 5a. The fourth electrode 8a is also the spiral induction electrode 100 shown in FIG. 2.

The fourth electrode 8a is disposed in the electrolytic tank (not shown) and is in contact with the electrolyte. The third switch 9a is connected between the second electrode 3a and the other power supply unit 5a, or between the fourth electrode 8a and the other power supply unit 5a.

The power supply unit 5a and the other power supply unit 5a each have a positive electrode and a negative electrode. If the first electrode 2a is electrically connected to the positive electrode of the power supply unit 5a, the second electrode 3a is electrically connected to the negative electrode of the other power supply unit 5a; if the first electrode 2a is electrically connected to the negative electrode of the power supply unit 5a, the second electrode 3a is electrically connected to the positive electrode of the other power supply unit 5a, such that the first electrode 2a and the second electrode 3a have opposite polarities. The first electrode 2a has the same polarity as the fourth electrode 8a. The second electrode 3a has the same polarity as the third electrode 4a.

When the total number of the electrodes is four, the first electrode 2a serves as the common electrode, the second electrode 3a serves as the central electrode and the common electrode simultaneously, both the third electrode 4a and the fourth electrode 8a serve as the peripheral electrodes, the first switch 6a serves as the central switch, and both the second switch 7a and the third switch 9a serve as the peripheral switches.

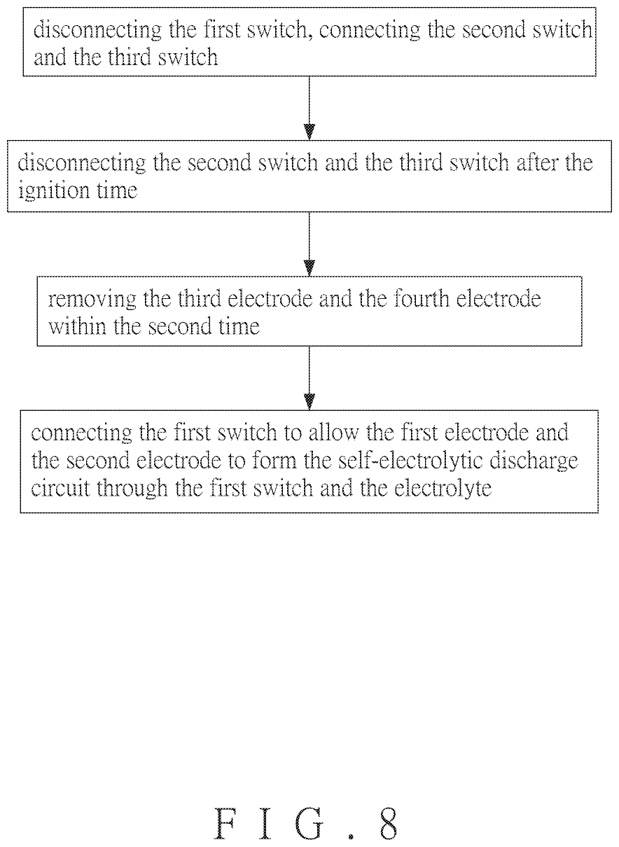

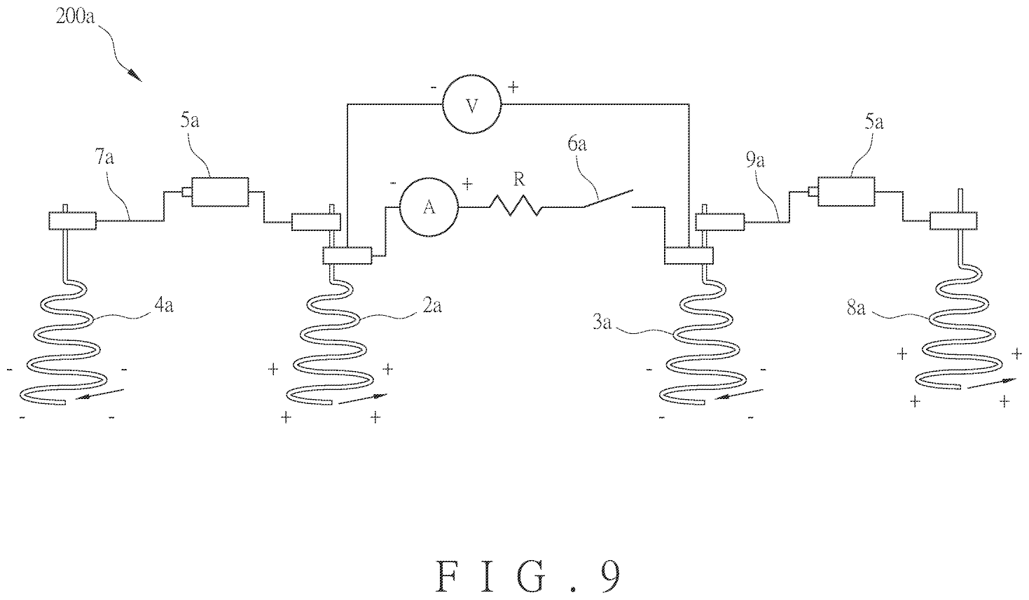

Please refer to FIG. 8 and FIG. 9 that are different from the first embodiment. When the electrolytic discharge system 200a of the second embodiment is used for performing the electrolytic discharge method, the first switch 6a is first disconnected, and then the second switch 7a and the third switch 9a are connected, so that the first electrode 2a, the third electrode 4a and the power supply units 5a form the electrolytic circuit through the second switch 7a and the electrolyte, and the second electrode 3a, the fourth electrode 8a and the other power supply unit 5a form the electrolytic circuit through the third switch 9a and the electrolyte.

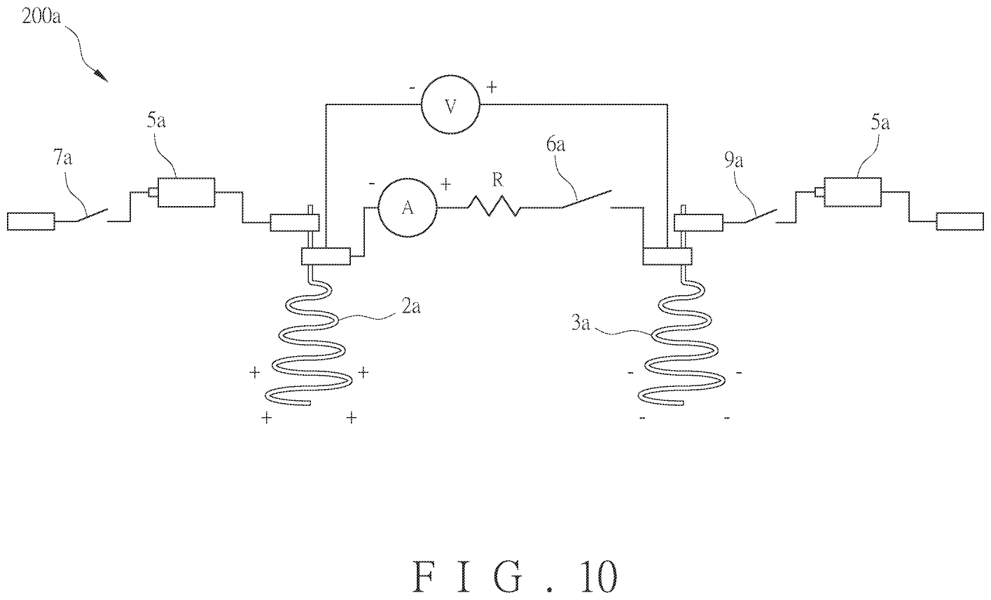

Please refer to FIG. 8 and FIG. 10. The power supply of the power supply unit 5a is also cut off after the ignition time, and the second switch 7a and the third switch 9a are disconnected. Then, the third electrode 4a and the fourth electrode 8a shown in FIG. 9 are removed within the specified time (second time). The potential difference is formed between the first electrode 2a and the second electrode 3a due to the difference in material energy levels of the first electrode 2a and the second electrode 3a and/or the electrical neutrality of the electrolyte being destroyed.

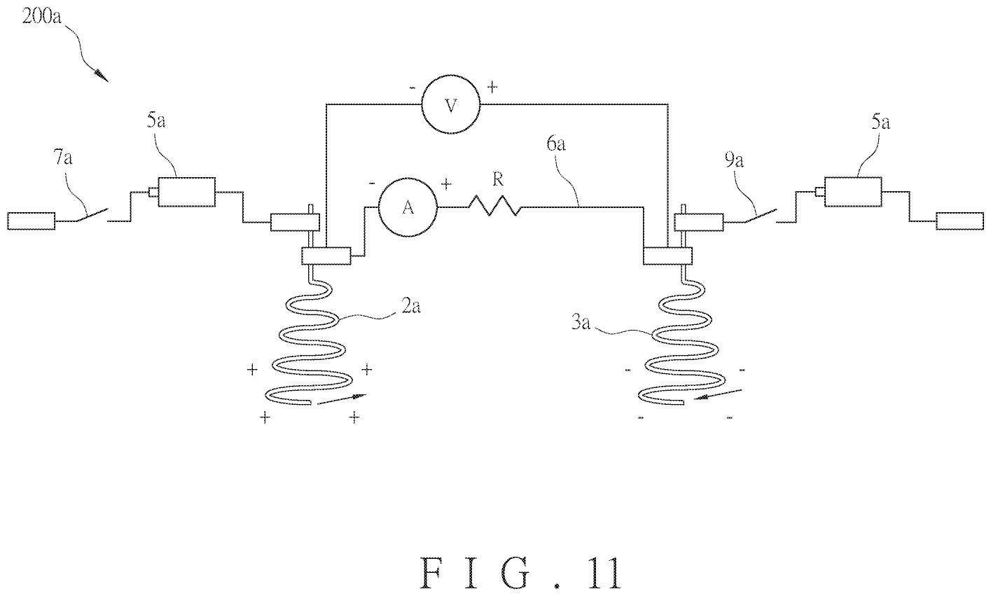

Please refer to FIG. 8 and FIG. 11. Finally, the first switch 6a is connected, so that the first electrode 2a and the second electrode 3a form the self-electrolytic discharge circuit through the first switch 6a and the electrolyte.

Same as the first embodiment, the potential difference forms the electric current, and the electric current flowing through the spiral induction electrode 100 forms the magnetic field on the spiral induction electrode 100 (referring to FIG. 2). Due to the shape of the spiral induction electrode 100, the density of the magnetic field changes as the spiral induction electrode 100 is gradually enlarged/tapered, thereby inducing various ions of the electrolyte 2021 to flow and become an ion flow, even inducing the ion flow to accelerate to pass through the spiral induction electrode 100 or inducing the electric current to increase in magnitude, such that the efficiency of the electrolysis effect is improved greatly.

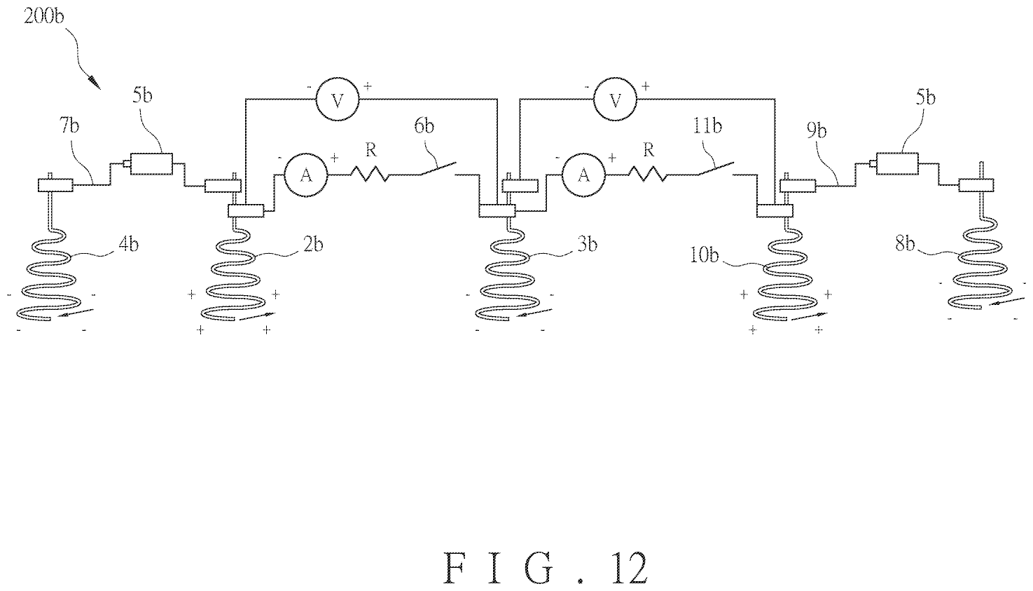

FIG. 12 illustrates a third embodiment of the electrolytic discharge system 200b of the present invention. The third embodiment is substantially similar to the second embodiment with the exceptions described below. The third embodiment further comprises a fifth electrode 10b, a fourth switch 11b, and a further power supply unit 5b. The fifth electrode 11b is also the spiral induction electrode 100 shown in FIG. 2.

The fifth electrode 10b is disposed in the electrolytic tank (not shown) and is in contact with the electrolyte. The fourth switch 11b is connected between the second electrode 3b and the fifth electrode 10b. The polarity of the second electrode 3b is opposite to that of the first electrode 2b and the fifth electrode 10b. The second electrode 3b, the third electrode 4b, and the fourth electrode 8b have the same polarity.

When the total number of the electrodes is five, the first electrode 2b and the fifth electrode 10b serve as the common electrodes, the second electrode 3b serves as the central electrode, both the third electrode 4b and the fourth electrode 8b serve as the peripheral electrodes, both the first switch 6b and the fourth switch 11b serve as the central switches, and both the second switch 7b and the third switch 9b serve as the peripheral switches.

Similar to the second embodiment, in this embodiment, the first switch 6b and the fourth switch 11b serving as the central switches are first disconnected, the second switch 7b and the third switch 9b serving as the peripheral switches are connected, the power supply is cut off after the ignition time, and the peripheral switches are disconnected.

The peripheral electrodes are removed within a specified time. By connecting the central switch, the common electrode and the central electrode form the self-electrolytic discharge circuit through the central switch and the electrolyte.

When the total number of the electrodes is six or more, an additional set of the common electrode and the peripheral electrode is connected outwardly from the central electrode in the electrolytic discharge system 200a shown in FIG. 7 or the electrolytic discharge system 200b shown in FIG. 12. The same steps are performed to increase the efficiency of the electrolysis effect. If the total number of the electrodes is an even number, the polarity of the electrodes will correspond to the second embodiment. If the total number of the electrodes is an odd number, the polarity of the electrodes will correspond to the third embodiment.

Both the first electrolytic discharge system 200 of the first embodiment and the second electrolytic discharge system 200a of the second embodiment are first energized with a small amount of electric current and then de-energized after the ignition time. Subsequently, without the need for energization, the spiral induction electrode 100 and the electrolyte obtain several times to dozens of times the electric current output, forming a discharge system with a net gain of energy. Besides, the electrolyte is used for self-electrolytic discharge, which can reduce carbon emissions and save energy greatly.

In addition, it should be noted that in FIG. 2, the spiral induction electrodes 100 are briefly drawn in the electrolytic tank 1 to illustrate that the spiral induction electrodes 100 are in contact with the electrolyte. The thick solid-line arrows indicate the direction of the magnetic field generated by the spiral induction electrodes 100. The thin solid-line arrows indicate the direction of electric current flowing through the spiral induction electrodes 100. The different dashed-line arrows indicate the direction of the ion flow with different flow speeds after induction.

Please refer to FIG. 1 and FIG. 9. In different types of implemented samples of the electrolyte:

In the case of three electrodes, i.e., the electrolytic discharge system 200, multi-core tin-plated copper and lead-free solder are used as the materials of the electrodes. The electrolyte is prepared in three different conditions: 60 milliliters of 1 M potassium nitrate and 0.6 M potassium hydroxide; 60 milliliters of 1.5 M potassium nitrate and 0.9 M potassium hydroxide; 60 milliliters of 2 M potassium nitrate and 1.6 M potassium hydroxide. According to the experimental results, the input power is increased from 0.65 mAh to the output power of 53.98 mAh; the input power is increased from 1.1389 mAh to the output power of 366.35 mAh; the input power is increased from 0.7153 mAh to the output power of 36.15 mAh, respectively. This is equivalent to increasing the discharge capacity by 50 to 321 times.

In the case of four electrodes, i.e., the electrolytic discharge system 200a, multi-core tin-plated copper and lead-free solder are used as the materials of the electrodes, and the electrolyte is 60 milliliters of 1.81 M potassium nitrate and 0.56 M potassium hydroxide. The input power is increased from 1.5739 mAh to the output power of 9.8814 mAh. If aluminum (0.428 g) and zinc are used as the materials of different electrodes, and the electrolyte is 60 milliliters of 1.2 M potassium nitrate and 0.75 M potassium hydroxide. The input power is increased from 0.0574 mAh to the output power of 972 mAh for 30 hours. Compare the theoretical capacity of aluminum (2980 mAh per gram), the measured capacity at this time is 2206 mAh per gram, with a material conversion rate of 76.21%.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. An electrolytic discharge method, comprising:
providing at least three electrodes that are all in contact with an electrolyte in an electrolytic tank, wherein the electrodes include at least one common electrode, a central electrode, and at least one peripheral electrode;
connecting a central switch between the adjacent common electrode and the central electrode;
connecting a peripheral switch and a power supply unit between the adjacent common electrode and the peripheral electrode;
by disconnecting the peripheral switch, the adjacent peripheral electrode, the power supply unit, and the common electrode and/or the central electrode forming an electrolytic circuit through the peripheral switch and the electrolyte;
performing a process for destroying electrical neutrality, wherein a potential difference is formed between the common electrode and the central electrode due to a difference in material energy levels of the common electrode and the central electrode and/or an electrical neutrality of the electrolyte being destroyed, the adjacent common electrode and the central electrode form a self-electrolytic discharge circuit through the central switch and the electrolyte.

2. The electrolytic discharge method as claimed in claim 1, wherein the common electrode and/or the central electrode is a spiral induction electrode, the spiral induction electrode extends spirally in an axial direction, in the axial direction, the spiral induction electrode has a first end and an opposing second end, an interior of the spiral induction electrode is fully hollow from the first end to the second end; after the self-electrolytic discharge circuit is formed, a magnetic field is formed on the spiral induction electrode through the potential difference, and the magnetic field induces ions of the electrolyte to flow and become an ion flow.

3. The electrolytic discharge method as claimed in claim 2, wherein in a radial direction perpendicular to the axial direction, the spiral induction electrode has at least two different radial widths; when the magnetic field is formed on the spiral induction electrode, the magnetic field induces the ion flow of the electrolyte to accelerate to pass through the spiral induction electrode, and/or the magnetic field induces an electric current on the spiral induction electrode to increase in magnitude.

4. The electrolytic discharge method as claimed in claim 1, wherein when the number of the electrodes is three, the process for destroying electrical neutrality is that after the electrolytic circuit is formed and after an ignition time, the central switch is disconnected and then the peripheral switch is disconnected; the peripheral electrode is removed within a specified time, by connecting the central switch, the potential difference is formed between the common electrode and the central electrode due to the difference in the material energy levels of the common electrode and the central electrode and/or the electrical neutrality of the electrolyte being destroyed.

5. The electrolytic discharge method as claimed in claim 4, wherein before connecting the peripheral switch, the central switch is first connected, and then the peripheral switch is connected.

6. The electrolytic discharge method as claimed in claim 1, wherein when the number of the electrodes is four or more, before connecting the peripheral switch, the central switch is first disconnected, and then the peripheral switch is connected.

7. The electrolytic discharge method as claimed in claim 6, wherein when the number of the electrodes is four or more, the process for destroying electrical neutrality is that after an ignition time, the peripheral switch is disconnected; the peripheral electrode is removed within a specified time, by connecting the central switch, the common electrode and the central electrode form the self-electrolytic discharge circuit through the central switch and the electrolyte.

8. An electrolytic discharge system, comprising:
an electrolytic tank, configured for storing an electrolyte;
at least three electrodes, disposed in the electrolytic tank and being in contact with the electrolyte, the electrodes including at least one common electrode, a central electrode, and at least one peripheral electrode;
at least one power supply unit, connected between the adjacent common electrode and the peripheral electrode;
at least one a central switch, connected between the adjacent common electrode and the central electrode;
at least one peripheral switch, connected between the adjacent common electrode and the power supply unit, or, connected between the adjacent common electrode and the peripheral electrode;
wherein by disconnecting the peripheral switch, the adjacent peripheral electrode, the power supply unit, and the common electrode and/or the central electrode form an electrolytic circuit through the peripheral switch and the electrolyte;
wherein a process for destroying electrical neutrality is performed, a potential difference is formed between the common electrode and the central electrode due to a difference in material energy levels of the common electrode and the central electrode and/or an electrical neutrality of the electrolyte being destroyed, the adjacent common electrode and the central electrode form a self-electrolytic discharge circuit through the central switch and the electrolyte.

9. The electrolytic discharge system as claimed in claim 8, wherein the common electrode and/or the central electrode is a spiral induction electrode, the spiral induction electrode extends spirally in an axial direction, in the axial direction, the spiral induction electrode has a first end and an opposing second end, an interior of the spiral induction electrode is fully hollow from the first end to the second end; after the self-electrolytic discharge circuit is formed, a magnetic field is formed on the spiral induction electrode through the potential difference, and the magnetic field induces ions of the electrolyte to flow and become an ion flow.

10. The electrolytic discharge system as claimed in claim 9, wherein in a radial direction perpendicular to the axial direction, the spiral induction electrode has at least two different radial widths; when the magnetic field is formed on the spiral induction electrode, the magnetic field induces the ion flow of the electrolyte to accelerate to pass through the spiral induction electrode, and/or the magnetic field induces an electric current on the spiral induction electrode to increase in magnitude.

11. The electrolytic discharge system as claimed in claim 8, wherein when the number of the electrodes is three, the process for destroying electrical neutrality is that after the electrolytic circuit is formed and after an ignition time, the central switch is disconnected and then the peripheral switch is disconnected; the peripheral electrode is removed within a specified time, by connecting the central switch, the potential difference is formed between the common electrode and the central electrode due to the difference in the material energy levels of the common electrode and the central electrode and/or the electrical neutrality of the electrolyte being destroyed.

12. The electrolytic discharge system as claimed in claim 11, wherein before connecting the peripheral switch, the central switch is first connected, and then the peripheral switch is connected.

13. The electrolytic discharge system as claimed in claim 8, wherein when the number of the electrodes is four or more, before connecting the peripheral switch, the central switch is first disconnected, and then the peripheral switch is connected.

14. The electrolytic discharge system as claimed in claim 13, wherein when the number of the electrodes is four or more, the process for destroying electrical neutrality is that after an ignition time, the peripheral switch is disconnected; the peripheral electrode is removed within a specified time, by connecting the central switch, the common electrode and the central electrode form the self-electrolytic discharge circuit through the central switch and the electrolyte.

15. The electrolytic discharge system as claimed in claim 8, wherein when the number of the electrodes is an even number of four or more, one of the common electrodes serves as the central electrode, a polarity of the central electrode is opposite to that of the other common electrodes, and a polarity of the common electrode is opposite to that of the adjacent peripheral electrode.

16. The electrolytic discharge system as claimed in claim 8, wherein when the number of the electrodes is an odd number of more than four, a polarity of the central electrode is the same as that of the peripheral electrode, and the polarity of the central electrode is opposite to that of the common electrode.

17. The electrolytic discharge system as claimed in claim 8, wherein the electrolytic tank is made of an insulating material, and the electrolyte is a single electrolyte or a composite electrolyte.

18. The electrolytic discharge system as claimed in claim 9, wherein the spiral induction electrode is formed by one of a tin-plated copper wire, a silver-plated copper wire, a lead-containing solder wire and a lead-free solder wire, or a combination thereof.
